(19) United States
(12) Patent Application Publication
(10) Pub. No.: US 2009/0029518 A1
(43) Pub. Date: Jan. 29, 2009

(54) Method of fabricating schottky barrier diode

(75) Inventor: Tadaaki Souma, Tsurugashima-shi (JP)

Correspondence Address: COHEN, PONTANI, LIEBERMAN & PAVANE LLP, 551 FIFTH AVENUE, SUITE 1210, NEW YORK, NY, 10176, US

(73) Assignee: Toko, Inc., Tokyo (JP)

(21) Appl. No.: 12/220,142

(22) Filed: Jul. 22, 2008

(30) Foreign Application Priority Data
Jul. 27, 2007 (JP) 2007-195560

(51) Int. Cl. H01L 21/8222

(52) U.S. Cl. 438/328; 257/E21.608

(57) ABSTRACT

Disclosed is a method of fabricating a Schottky barrier diode, which comprises the steps of laminating an N⁻ type epitaxial layer having a thickness of 2 to 4 μm, on an N⁺ type substrate layer, to form a semiconductor substrate; forming a P⁺ type guard ring at a given position of epitaxial layer, from the side of a top surface of the semiconductor substrate; dividing a portion of the epitaxial layer surrounded by the guard ring, into a plurality of unit regions each having one side length of 0.1 to 0.5 mm, and forming an N type Schottky contact region and a P⁺ type element-segmenting region surrounding the Schottky contact region, within each of the unit regions; forming an insulation layer on a portion of the top surface of the semiconductor substrate other than the Schottky contact regions; forming a barrier metal on each of top surfaces of the Schottky contact regions; forming a first electrode on the side of the top surface of the semiconductor substrate in such a manner as to be electrically connected to all of the barrier metals; and forming a second electrode on the side of a bottom surface of the semiconductor substrate in such a manner as to be electrically connected to the substrate layer.

### BACKGROUND OF THE INVENTION

1. Field of the Invention

The present invention relates to a method of fabricating a Schottky barrier diode. In particular, the present invention relates to a fabrication method suitable for forming a Schottky barrier diode for high power applications.

2. Description of the Prior Art

Heretofore, there has been known a Schottky barrier diode (hereinafter referred to as “SBD”) having a rectifying action utilizing a potential barrier produced by contact between a metal and a semiconductor. The SBD has been widely used in various circuits for high-speed switching, frequency conversion and detection.

FIGS. 1A and 1B show the structure of the conventional SBD, wherein FIG. 1A is a top view thereof, and FIG. 1B is a sectional view taken along the line C-C′ in FIG. 1A. In a typical SBD, a semiconductor substrate is used which comprises an n⁺ type substrate layer (hereinafter referred to as “substrate layer”) 1 having a thickness ts of about 200 μm, and an n⁻ type epitaxial growth layer (hereinafter referred to as “epitaxial layer”) 2 laminated on the substrate layer 1 in a thickness of about 5.0 μm. Then, a surface-protective insulation layer 4, such as an oxidized film, is formed on a surface of the epitaxial layer 2. A portion of the insulation layer 4 is removed, and a barrier metal 5 is provided in the removed portion. The resulting contact region between the barrier metal 5 and the epitaxial layer 2 serves as a Schottky contact region 10. The barrier metal 5 consists of a metal, such as Mo or Ti. A p⁺ type impurity is diffused around an outer periphery of the Schottky contact region 10 to provide a guard ring 3 in order to ensure given withstand voltage. An anode electrode 6 is provided on a top surface of the semiconductor substrate in such a manner as to cover the entire surface of the barrier metal 5, and a cathode electrode 7 is provided on a bottom surface of the semiconductor substrate. Each of the anode electrode 6 and the cathode electrode 7 is made of an electroconductive metal, such as Al.

In the SBD having the structure illustrated in FIGS. 1A and 1B, when a current is passed therethrough in a forward direction, a large number of carriers in the epitaxial layer 2 are moved to the barrier metal 5, so that it is immediately placed in a conduction state. By contrast, even if it is attempted to pass a current therethrough in a reverse direction, a large number of carriers in the epitaxial layer 2 are moved toward the substrate layer 1 to broaden a depletion layer, so that it will never be placed in the conduction state. Thus, the SBD operating based on a large number of carriers allows for a higher-speed switching operation, because a forward voltage (hereinafter referred to as “VF”) becomes lower, and a reverse recovery time becomes shorter, as compared with a PN-junction diode.

Recent years, there has been a growing need for further lowering a VF of a SBD for the purpose of a reduction in power consumption and others. For example, Japanese patent laid-open publication No. JP2000-332266A proposes a technique of reducing a thickness te of an epitaxial layer to lower the VF.

In case of forming a SBD for high power applications, it is necessary to increase a chip size to obtain a larger Schottky contact area, so as to pass a larger current therethrough. FIG. 2 shows a change in VF characteristic caused by a change in thickness of an epitaxial layer in a conventional SBD having a large chip size, wherein the chip size is 2.0 mm on a side L, and a barrier metal consists of Mo. As seen in FIG. 2, even if the thickness of the epitaxial layer 2 is reduced from 5.0 μm to 4.0 μm, almost no change is observed in the VF characteristic.

A VF of a SBD will be specifically looked into. It is considered that the VF of the SBD is determined by a plurality of factors including (1) a Schottky barrier ΦBn, (2) respective electric resistances of an epitaxial layer and a substrate layer, and (3) an electric resistance of a bonding wire. FIG. 3 shows a contribution rate of each of the factors to the VF (i.e., a VF contribution rate of each of the factors), with respect to a forward current (IF) of the SBD. The respective VF contribution rates of the factors are calculated using the following formulas:

$$\begin{matrix}VF ( 1 ) = \frac{kT}{q} \cdot \{ ln ( \frac{IF}{A \cdot {A}^{*} \cdot {T}^{2}} ) + \frac{q \cdot φ Bn}{kT} \} & ( 1 ) \\ VF ( 2 ) = \frac{IF}{A} \cdot \{ ρ e ( t e - Δ t ) + \frac{1}{2} ( ρ e - ρ s ) \cdot Δ t \} + \frac{IF}{A p} \cdot ρ s \cdot t s & ( 2 ) \\ VF ( 3 ) = IF \cdot W ρ \cdot \frac{Wt}{W} & ( 3 ) \\ R ( n ) = \frac{VF ( n )}{\sum VF ( n )} \times 100 , & ( 4 )\end{matrix}$$

wherein A: Schottky contact area, ρe: resistivity of the epitaxial layer,
ρs: resistivity of the substrate layer,
te: thickness of the epitaxial layer,
Δt: increment due to climbing phenomenon of the epitaxial layer,
ts: thickness of the substrate layer, Ap: pellet area, IF: forward current,
W: cross-sectional area of the bonding wire, Wt: length of the bonding wire
Wρ: resistivity of the bonding wire, Φ Bn: Schottky barrier,
K: Boltzmann's constant,
T: operating temperature (absolute temperature),
q: quantity of electron charge, and A*: Richardson's constant.

The formulas 1 to 3 are used for calculating respective VF values attributable to the factors. Specifically, the formula 1, the formula 2 and the formula 3 are used for calculating a VF value attributable to the Schottky barrier Φ Bn (hereinafter referred to as “Φ Bn”), a VF value attributable to the epitaxial layer and the substrate layer, and a VF value attributable to the bonding wire, respectively. The formula 4 is used for calculating the respective VF contribution rates of the factors.

In the formula 2, the increment Δt due to climbing phenomenon of the epitaxial layer is an ignorable value. When the increment Δt is ignored, the formula 2 can be disassembled and rewritten to the following formulas 5, 6. In this case, the formula 5 and the formula 6 are used for the epitaxial layer and the substrate layer, respectively.

$$\begin{matrix}VF ( epi ) = \frac{IF}{A} \cdot ρ e \cdot t e & ( 5 ) \\ VF ( sub ) = \frac{IF}{A p} \cdot ρ s \cdot t s & ( 6 )\end{matrix}$$

As seen in FIG. 3, as the IF is increased, the contribution rate of the Φ Bn becomes lower and the contribution rate of the epitaxial layer becomes higher. However, even in a high IF region, the contribution rate of the epitaxial layer is lower than that of the Φ Bn, and the Φ Bn still has a predominant influence.

Therefore, in the large-chip SBD for high power applications, it has been unable to effectively lower the VF based on only the conventional technique of reducing a thickness of the epitaxial layer.

In the conventional SBD, there has been employed a technique of changing a material of a barrier metal to adjust characteristics of the SBD. The Φ Bn is determined by an intrinsic work function Φm of the material of the barrier metal and an electron affinity x of a semiconductor. For example, the Φ Bn becomes higher as the material of the barrier metal has a higher work function Φm. Thus, the VF value can be lowered by using a barrier metal having a lower Φm (i.e., providing a lower Φ Bn).

However, it is known that there exists a trade-off relation between a VF and a reverse leakage current (hereinafter referred to as “IR”) in a SBD. That is, there is a problem that a reduction in the VF causes an increase in the IR, and inversely a reduction in the IR causes an increase in the VF.

FIGS. 4A and 4B are graphs showing respective characteristics of SBDs different in material of a barrier metal, wherein FIG. 4A shows forward characteristics, and FIG. 4B shows reverse characteristics. Ti and Mo illustrated in FIGS. 4A and 4B are commonly used materials of the barrier metal. A Φ Bn in Ti is 0.52 eV, and a Φ Bn in Mo is 0.67 eV. As seen in FIG. 4A, Ti can provide a lower VF, as compared with Mo. However, as seen in FIG. 4B, the reverse characteristic in Ti significantly deteriorates, as compared with Mo.

Therefore, it has been unable to improve the forward characteristic while adequately maintaining the reverse characteristic, based on the technique of changing the material of the barrier metal.

### SUMMARY OF THE INVENTION

It is an object of the present invention to provide a method of fabricating a SBD for high power applications, capable of improving a forward characteristic without causing deterioration of reverse characteristic.

The present invention provides a method of fabricating a SBD, which comprises the following steps.
(1) The step of forming a semiconductor substrate to have a structure including a first semiconductor region of a first conductivity type and a second semiconductor region of a same conductive type as that of the first semiconductor region with a lower impurity concentration than that of the first semiconductor region, wherein the second semiconductor region is laminated on the first semiconductor region in a thickness of 2.0 to 4.0 μm.
(2) The step of injecting an impurity of a second conductive type into a given position of the second semiconductor region, from the side of a top surface of the semiconductor substrate, to form a guard ring.
(3) The step of dividing a portion of the second semiconductor region surrounded by the guard ring into a plurality of unit regions each having one side length of 0.1 to 0.5 mm, and forming a Schottky contact region of the first conductive type and an element-segmenting region of the second conductive type surrounding the Schottky contact region, within each of the unit regions.
(4) The step of forming an insulation layer on a portion of the top surface of the semiconductor substrate other than the Schottky contact regions.
(5) The step of forming a barrier metal on each of top surfaces of the Schottky contact regions to form a Schottky contact between the barrier metal and the Schottky contact region.
(6) The step of forming a first electrode on the side of the top surface of the semiconductor substrate in such a manner as to be electrically connected to all of the barrier metals.
(7) The step of forming a second electrode on the side of a bottom surface of the semiconductor substrate in such a manner as to be electrically connected to the first semiconductor region.

According to the present invention, in the method of fabricating a large-chip SBD for high power applications, the Schottky contact region is divided into a plurality of unit regions (hereinafter referred to as “pellets”) each having a small contact area, by the element-segmenting regions. As a result of the division, in a high IF region, a VF contribution rate of the Φ Bn is reduced, and a VF contribution rate of the epitaxial layer is increased. The present invention utilizes this phenomenon. A combination of the technique of reducing a thickness of the epitaxial layer and the technique of dividing an element into a plurality of pellets makes it possible to effectively lower the VF even in a large-chip SBD.

The IR is determined by the Φ Bn and the Schottky contact area. Even if an element is divided into a plurality of pellets, the reverse characteristic is not significantly changed as long as there is not much difference in total area of Schottky contact region between before and after the division. Thus, the method of the present invention can improve the forward characteristic without causing deterioration of the reverse characteristic.

### BRIEF DESCRIPTION OF THE DRAWINGS

FIG. 1A is a top view showing a structure of a conventional SBD.

FIG. 1B is a sectional view showing the structure of the conventional SBD, taken along the line C-C′ in FIG. 1A.

FIG. 2 is a graph showing a change in forward characteristic caused by a change in thickness (5 μm→4 μm) of an epitaxial layer in a conventional large-chip SBD.

FIG. 3 is a graph showing a VF contribution rate with respect to a forward current (IF) in the conventional large-chip SBD.

FIG. 4A is a graph showing respective forward characteristics of SBDs different in material of a barrier metal.

FIG. 4B is a graph showing respective reverse characteristics of the SBDs different in material of the barrier metal.

FIG. 5A is a top view showing a structure of a SBD fabricated by a method according to a first embodiment of the present invention.

FIG. 5B is a sectional view taken along the line A-A′ in FIG. 5A.

FIG. 6 is a graph showing respective VF contribution rates of epitaxial layers different in pellet size.

FIG. 7 is a graph showing respective forward characteristics of SBDs having the epitaxial layers in FIG. 6.

FIG. 8 is a graph showing VF-value coefficients a, b in each chip size.

FIG. 9 is a graph showing a VF contribution rate with respect to a forward current (IF) in Example 1.

FIG. 10 is a graph showing a forward characteristic in Example 1.

FIG. 11 is a graph showing a VF lowering rate in Example 1.

FIG. 12 is a graph showing a reverse characteristic in Example 1.

FIG. 13A is a top view showing a structure of a SBD fabricated by a method according to a second embodiment of the present invention.

FIG. 13B is a sectional view taken along the line B-B′ in FIG. 13A.

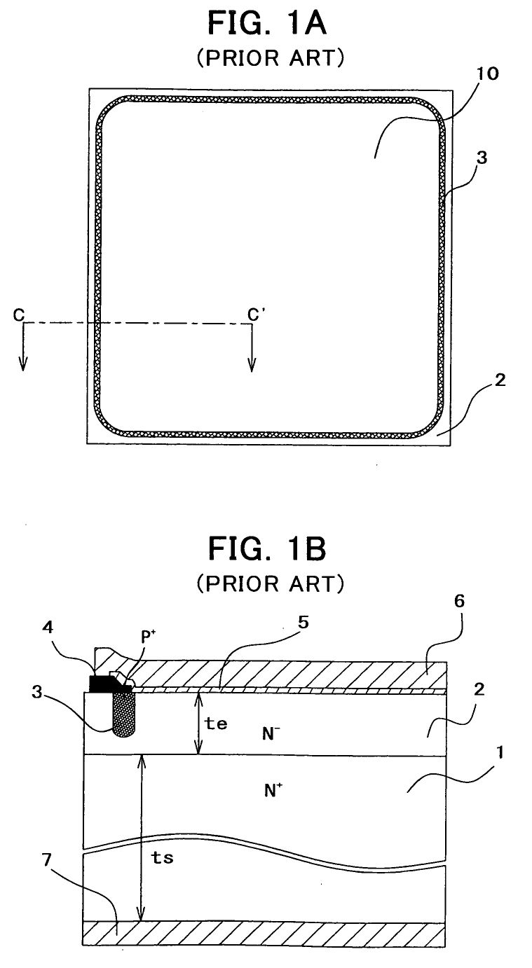

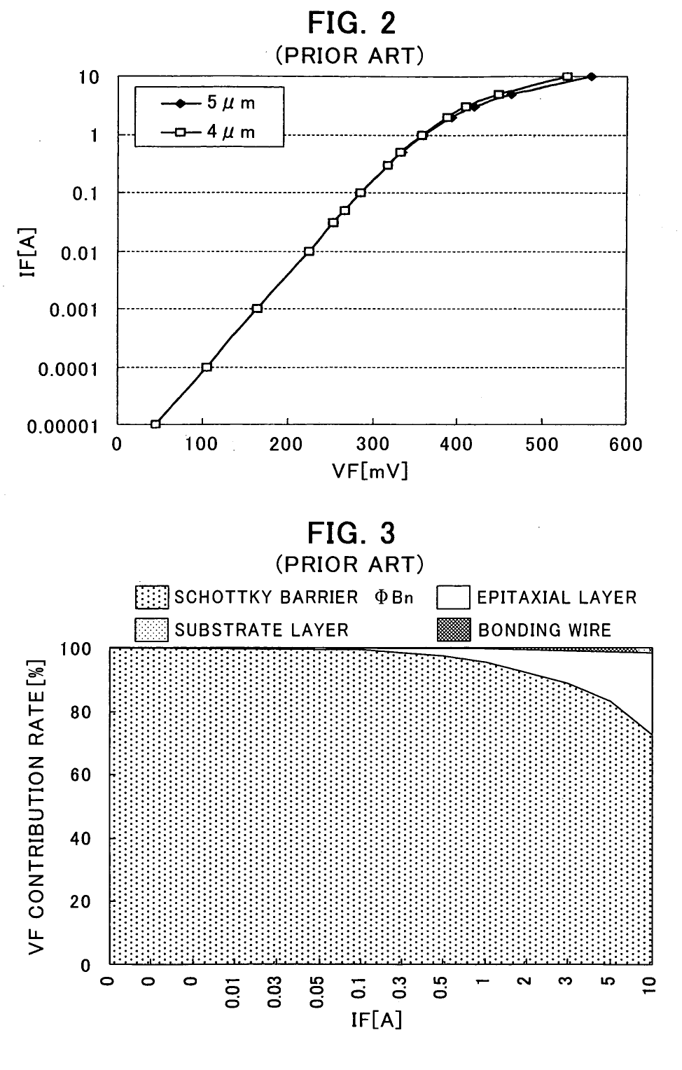

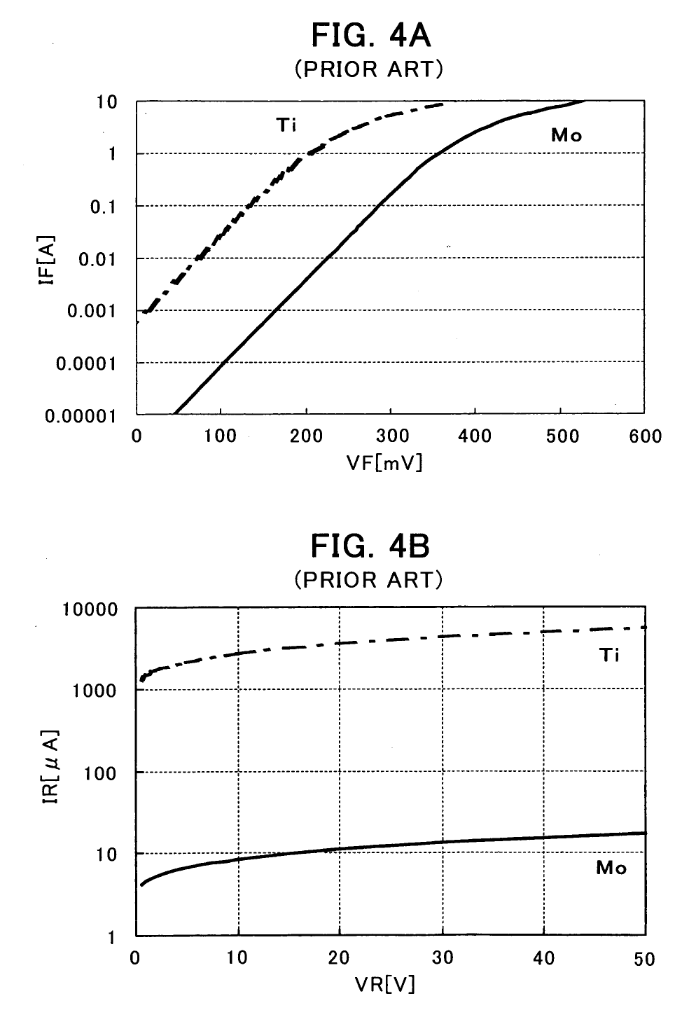

### DESCRIPTION OF THE PREFERRED EMBODIMENTS

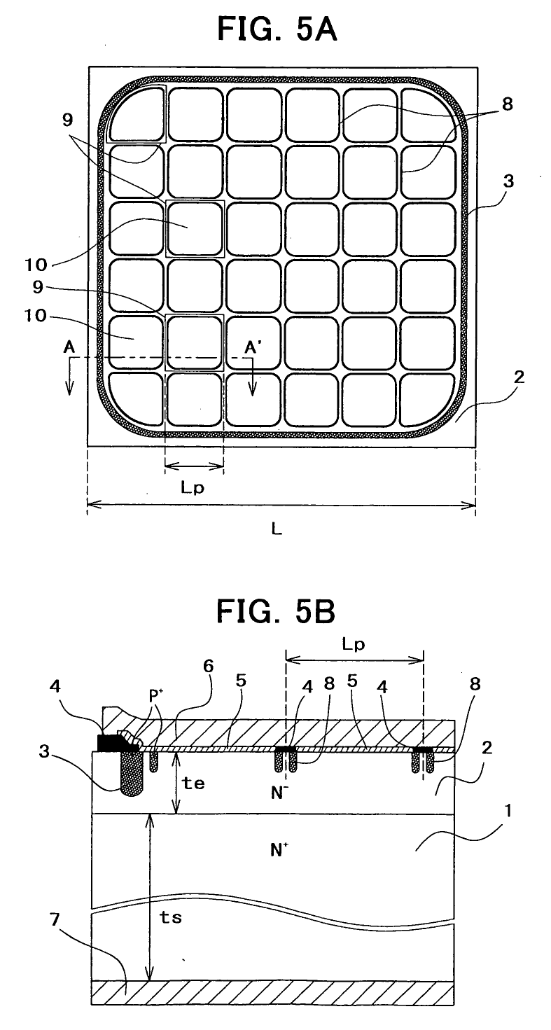

With reference to the drawings, a Schottky barrier diode (SBD) fabrication method of the present invention will now be described. FIGS. 5A and 5B show a structure of a SBD fabricated by a method according to a first embodiment of the present invention, wherein FIG. 5A is a top view of the SBD, and FIG. 5B is a sectional view taken along the line A-A′ in FIG. 5A.

In the method according to the first embodiment, a SBD is fabricated using a semiconductor substrate which comprises a substrate layer 1 (first semiconductor region) of an n⁺ type (first conductive type with a relatively high impurity concentration), and an epitaxial layer 2 (second semiconductor region) of an n⁻ type (first conductive type with a relatively low impurity concentration) formed on one of opposite principal surfaces of the substrate layer 1 by an epitaxial growth process or the like. The epitaxial layer 2 is formed to have a thickness te less than an average thickness of conventional epitaxial layers. A p type impurity (impurity of a second conductive type; e.g., boron) is selectively diffused into a surface region of the epitaxial layer 2 in a commonly known manner to form a frame-shaped p⁺ type guard ring 3. A portion of the epitaxial layer 2 surrounded by the guard ring 3 is divided into a plurality of pellets 9, and a p⁺ type element-segmenting region 8 is formed along an inner edge of each of the pellets 9. A portion of the epitaxial layer 2 surrounded by the element-segmenting region 8 serves as a Schottky contact region 10. After the element-segmenting regions 8 are formed, a Schottky contact area of the SBD is reduced by a total area of the element-segmenting regions 8. Thus, it is preferable to minimize a width of each of the element-segmenting regions 8.

Then, an insulation layer 4, such as an oxide film, is formed on a surface of the epitaxial layer 2 to protect the surface. Subsequently, a portion of the insulation layer 4 formed on the Schottky contact regions 10 is removed. A barrier metal 5 (e.g., Mo) is formed in each of opening portions created by removing the insulation layer 4, in such a manner as to come into Schottky contact with the epitaxial layer 2. Then, Al or the like is vapor-deposited on insulation layer 4 and the barrier metals 5 to form an anode electrode 6 (first electrode). Further, Al or the like is vapor-deposited on the other principal surface of the substrate layer 1 to form a cathode electrode 7 (second electrode).

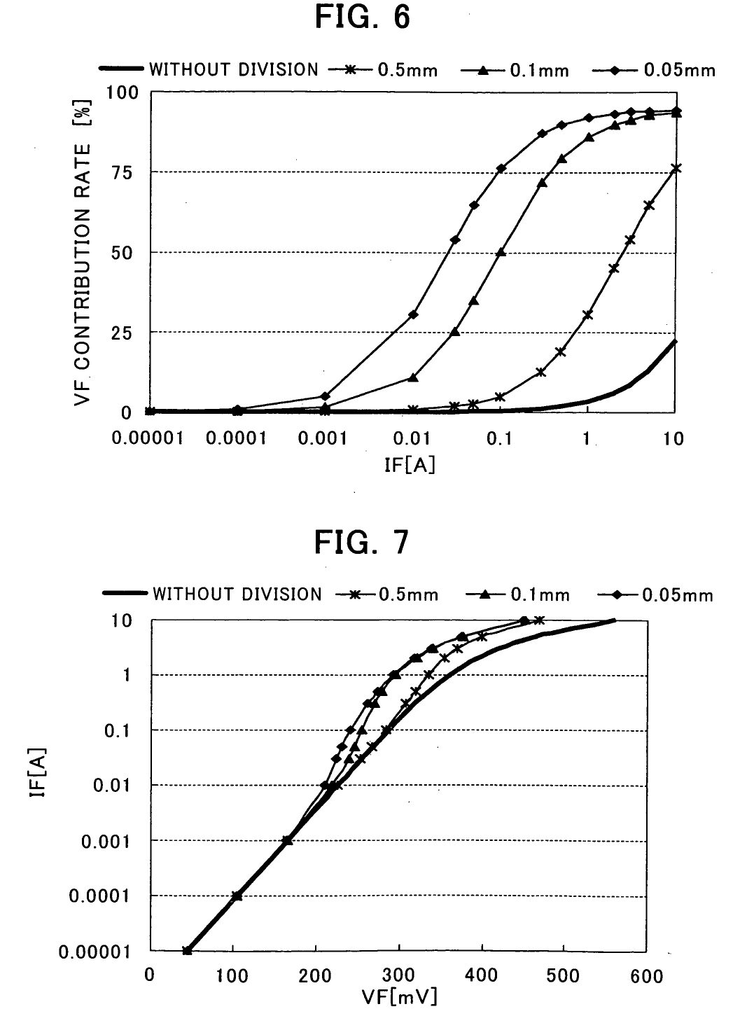

A principle of lowering in a VF and an effective range thereof in the SBD fabricated in the above manner will be described with reference to FIGS. 6 to 8.

The SBD fabrication method of the present invention is characterized by a combination of a technique of forming the epitaxial layer 2 to have a thickness less than an average thickness of conventional epitaxial layers, and a technique of dividing the Schottky contact region by the P+ type element-segmenting regions 8.

As is commonly known, a VF of a SBD can be lowered by reducing a thickness of an epitaxial layer 2. However, in case of a large chip size, the technique of reducing a thickness of the epitaxial layer 2 can provide only an extremely limited level of VF lowering effect.

When the Schottky contact region is divided into the plurality of pellets 9 by the P+ type element-segmenting regions 8, a VF contribution rate of each of the aforementioned factors is changed. Specifically, a VF contribution rate of the Φ Bn is reduced, and a VF contribution rate of the epitaxial layer is increased. Thus, the present invention is intended to achieve the object of lowering a VF of a large-chip SBD, based on a combination of the two techniques.

A pellet size in the SBD fabrication method of the present invention will be specifically described below. FIG. 6 shows respective VF contribution rates of epitaxial layers different in pellet size, and FIG. 7 shows respective forward characteristics of SBDs having the epitaxial layers in FIG. 6. The samples illustrated in FIGS. 6 and 7 are three types of SBDs formed with a plurality of pellets each having one side length Lp (hereinafter referred to as “pellet size”) of 0.05 mm, 0.1 mm and 0.5 mm, under common conditions that one side length L of a chip (hereinafter referred to as “chip size”) is set at 2.0 mm, and a thickness te of an epitaxial layer is set at 4.0 μm. FIGS. 6 and 7 also show a conventional SBD without division, as a comparative example.

As seen in FIGS. 6 and 7, as the pellet size is reduced, the VF contribution rate of the epitaxial layer becomes higher, and the VF becomes lower in a high IF region. Comparing between the sample having a pellet size of 0.05 mm and the sample having a pellet size of 0.1 mm, the VF is lowered at approximately the same level in the high IF region. If the pellet size is excessively reduced, an area of the element-segmenting regions 8 is increased to cause undesirable reduction in the Schottky contact area of the SBD. Thus, it is only necessary to reduce the pellet size to about 0.1 mm.

In a pellet size of 0.5 mm, when the thickness of the epitaxial layer is reduced from 5.0 μm to 4.0 μm, the VF can be lowered by about 15% in the high IF region. Just for reference, in the conventional structure, when the thickness of the epitaxial layer is reduced from 5.0 μm to 4.0 μm, the VF is lowered by about 5% in the high IF region. That is, the above lowering rate is about three times greater than that in the conventional structure without division, and therefore it can be said that even the SBD having a pellet size of about 0.5 mm has a sufficient VF lowering effect.

Therefore, in the present invention, the pellet size is preferably set in the range of about 0.1 to 0.5 mm. More preferably, the pellet size is set at about 0.3 mm in view of a current fabrication accuracy, and a reduction in the Schottky contact area due to the element-segmenting regions.

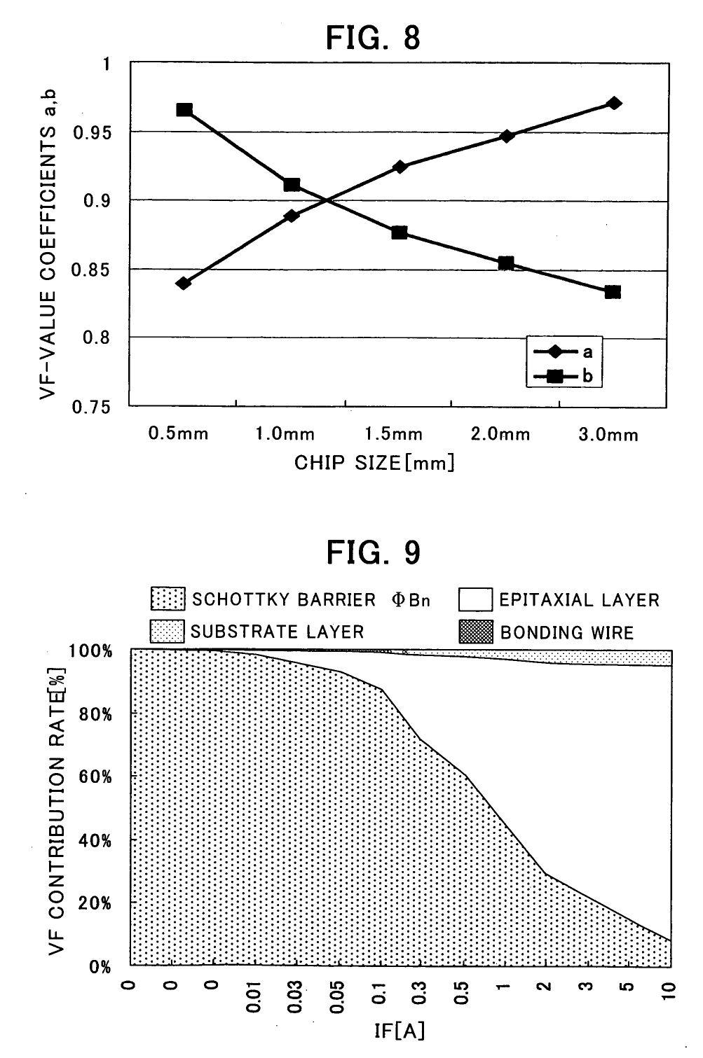

A preferred chip size in the present invention will be described below. FIG. 8 shows VF-value coefficients a, b in each chip size. The VF-value coefficients a, b are determined on the basis of a VF value obtained when an IF of a SBD having an epitaxial layer with a thickness te of 5.0 μm and a non-divided Schottky contact region is 10 A. Given that the VF value obtained at that time is VF₁. The VF-value coefficient a represents a level of VF value to be obtained when the thickness te of the epitaxial layer is reduced from 5.0 μm to 4.0 μm. Given that the VF value obtained at that time is VF₂. The VF-value coefficient b represents a level of VF value to be obtained when the Schottky contact region is additionally divided to have a pellet size of 0.1 mm. Given that the VF value obtained at that time is VF₃. In this case, the thickness te of the epitaxial layer is 4.0 μm.

A relation between respective ones of the VF values and the VF-value coefficients can be expressed in the following formula: VF₃=b·VF₂=ab·VF₁. The VF-value coefficient a is indicative of an influence of a change in thickness of the epitaxial layer on the VF, and the VF-value coefficient b is indicative of an influence of division of the Schottky contact region on the VF. That is, a smaller value of the VF-value coefficient a relative to 1.0 means that the change in thickness of the epitaxial layer is more effective in lowering the VF value. A smaller value of the VF-value coefficient b relative to 1.0 means that the division of the Schottky contact region is more effective in lowering the VF value.

As seen in FIG. 8, as the chip size is increased, the VF-value coefficient a becomes larger, and the VF-value coefficient b becomes smaller. That is, as the chip size is increased, the VF lowering effect based on the change in thickness of the epitaxial layer becomes smaller, and the VF lowering effect based on the division of the Schottky contact region becomes larger.

When the chip size is 1.0 mm or less, the VF-value coefficient a is smaller than the VF-value coefficient b. This means that the change in thickness of the epitaxial layer has a larger influence on the VF value than the division of the Schottky contact region. Thus, in this case, the VF value can be sufficiently lowered only by changing the thickness of the epitaxial layer, without using the fabrication method of the present invention.

When the chip size is 1.5 mm or more, the VF-value coefficient b is smaller than the VF-value coefficient a, and therefore the division of the Schottky contact region has a larger influence on the VF value than the change in thickness of the epitaxial layer. Thus, in a SBD having a chip size of 1.5 mm or more, the VF value cannot be sufficiently lowered only by changing the thickness of the epitaxial layer. In this case, the Schottky contact region can be divided using the fabrication method of the present invention to sufficiently lower the VF value.

As above, the SBD fabrication method of the present invention is preferably performed for an SBD having a chip size of 1.5 mm or more.

A specific example of a Schottky barrier diode (SBD) fabricated by the method of the present invention will be shown below. In particular, a specific example of a Schottky barrier diode (SBD) fabricated by the method according to the first embodiment of the present invention will be described with reference to the drawings. FIGS. 5A and 5B show a structure of a SBD fabricated by the method according to the first embodiment of the present invention, wherein FIG. 5A is a top view of the SBD, and FIG. 5B is a sectional view taken along the line A-A′ in FIG. 5A. In this example (Example 1), a SBD will be described on the following assumption: a chip has one side length L of 2.0 mm; an epitaxial layer has a thickness te of 4.0 μm; and each pellet has one side length Lp of 0.3 mm.

In Example 1, the SBD was fabricated using a semiconductor substrate which comprises an n⁺ type substrate layer 1 having a thickness ts of about 200 μm, and an n⁻ type epitaxial layer 2 formed on one of opposite principal surfaces of the substrate layer 1 by an epitaxial growth process or the like. A thickness te of the epitaxial layer 2 was set at about 4.0 μm. Then, a mask was formed on a surface of the epitaxial layer 2, and a p type impurity was diffused into the surface to form a frame-shaped p⁺ type guard ring 3 at a desired position of the surface. A portion of the epitaxial layer 2 surrounded by the guard ring 3 preferably has an area which is 85% or more of a chip area.

The portion of the epitaxial layer 2 surrounded by the guard ring 3 was divided into thirty six pellets 9 each having one side length Lp of about 0.3 mm, and a frame-shaped p⁺ type element-segmenting region 8 was formed along an inner edge of each of the pellets 9. The guard ring 3 and the element-segmenting regions 8 may be simultaneously formed. A portion of the epitaxial layer 2 surrounded by the element-segmenting region 8 serves as a Schottky contact region 10.

Then, an insulation layer 4, such as an oxide film, was formed on a surface of the epitaxial layer 2 to protect the surface, and a portion of the insulation layer 4 formed on the Schottky contact regions 10 was removed. A Mo barrier metal 5 was formed in each of opening portions created by removing the insulation layer 4, in such a manner as to come into Schottky contact with the epitaxial layer 2. Then, Al was vapor-deposited on insulation layer 4 and the barrier metals 5 to form an anode electrode 6 in such a manner as to allow the barrier metals 5 to come into contact with the anode electrode 6. Further, Al was vapor-deposited on the other principal surface of the substrate layer 1 to form a cathode electrode 7.

FIG. 9 shows a VF contribution rate with respect to a forward current (IF) in Example 1. As seen in FIG. 9, in Example 1, a VF contribution rate of the ΦBn is more lowered in a high IF region as compared with the conventional SBD, and a VF contribution rate of the epitaxial layer becomes predominant in place of the ΦBn. In Example 1, when the IF is 10 A, the VF contribution rate of the epitaxial layer is increased up to about 90%.

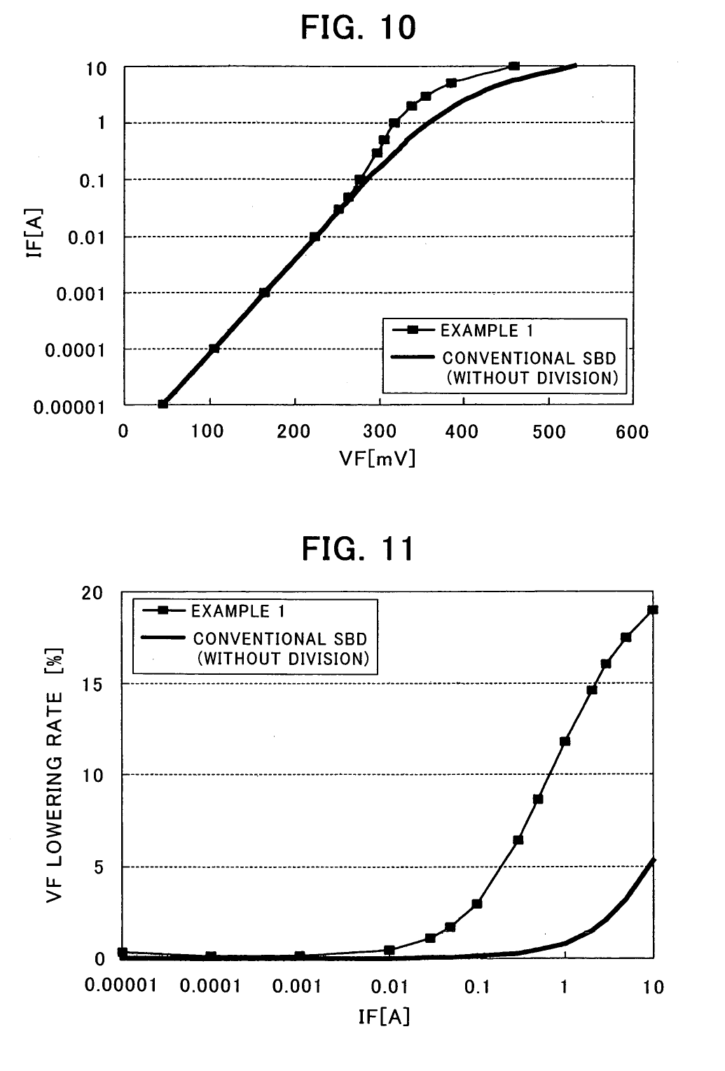

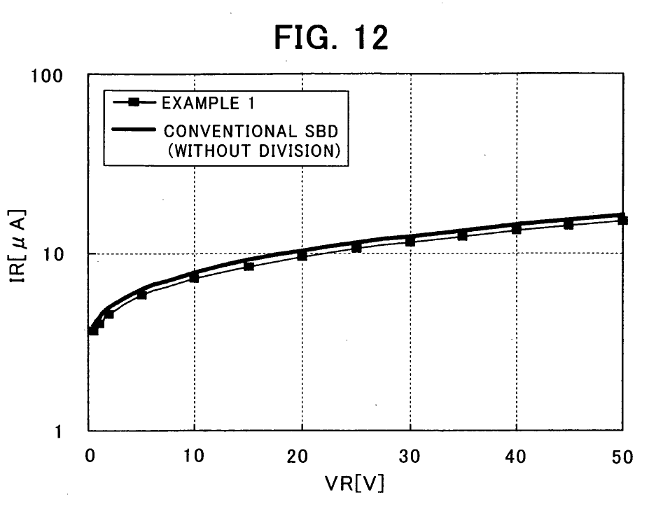

FIG. 10 shows a forward characteristic in Example 1, wherein a forward characteristic of the conventional SBD (without division) is also shown therein for comparison. As seen in FIG. 10, as compared with the conventional SBD, the VF in Example 1 is largely lowered in the high IF region. FIG. 11 shows a VF lowering rate in Example 1. As seen in FIG. 11, a VF lowering rate in Example 1 is largely increased in the high IF region, in conjunction with a change in the VF contribution rate of the epitaxial layer. When the IF is about 5 A at which a SBD for high power applications is typically operated, the conventional SBD can lower the VF only by about 3%, whereas the SBD in Example 1 could lower the VF by about 17%. FIG. 12 shows a reverse characteristic in Example 1. As seen in FIG. 12, the SBD in Example 1 can prevent deterioration of the reverse characteristic.

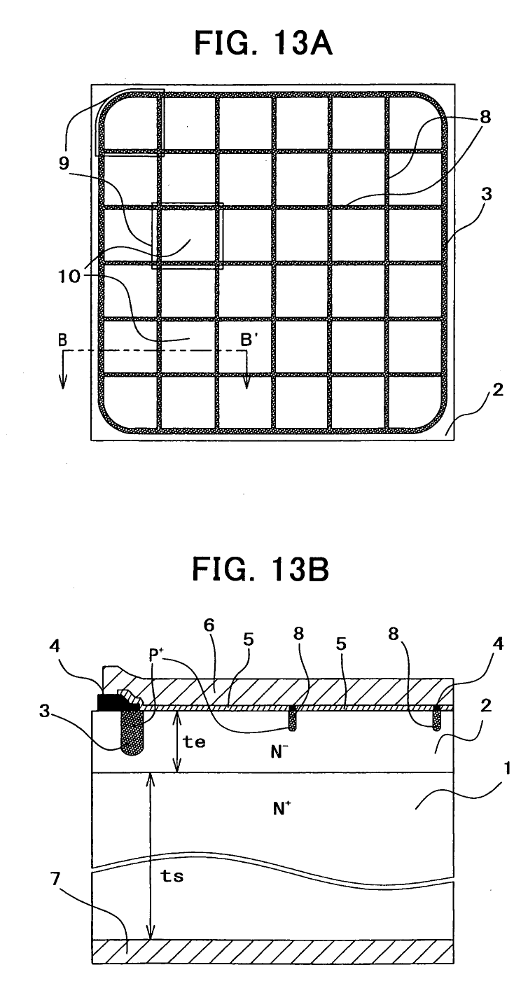

FIGS. 13A and 13B show a structure of a SBD fabricated by a method according to a second embodiment of the present invention, wherein FIG. 13A is a top view of the SBD, and FIG. 13B is a sectional view taken along the line B-B′ in FIG. 13A. The method according to the second embodiment is different from the method according to the first embodiment, in that the element-segmenting regions 8 are formed in a latticed pattern. The remaining fabrication steps and effects are the same as those in the first embodiment, and their description will be omitted.

When the element-segmenting regions 8 are formed in a latticed pattern as shown in FIGS. 13A and 13B, a total area of the element-segmenting regions 8 can be reduced to provide an advantage of being able to suppress a reduction in Schottky contact area.

What is claimed is:

1. A method of fabricating a Schottky barrier diode utilizing a Schottky contact between a semiconductor substrate and a barrier metal, comprising the steps of:
forming said semiconductor substrate to have a structure including a first semiconductor region of a first conductivity type and a second semiconductor region of a same conductive type as that of said first semiconductor region with a lower impurity concentration than that of said first semiconductor region, wherein said second semiconductor region is laminated on said first semiconductor region in a thickness of 2.0 to 4.0 μm;
injecting an impurity of a second conductive type into a given position of said second semiconductor region, from the side of a top surface of said semiconductor substrate, to form a guard ring;
dividing said second semiconductor region surrounded by said guard ring into a plurality of unit regions each having one side length of 0.1 to 0.5 mm, and forming a Schottky contact region of said first conductive type and an element-segmenting region of said second conductive type surrounding said Schottky contact region, within each of said unit regions;
forming an insulation layer on said top surface of said semiconductor substrate other than said Schottky contact regions;
forming a barrier metal on each of top surfaces of said Schottky contact regions to form a Schottky contact between said barrier metal and said Schottky contact region;
forming a first electrode on the side of said top surface of said semiconductor substrate in such a manner as to be electrically connected to all of said barrier metals; and
forming a second electrode on the side of a bottom surface of said semiconductor substrate in such a manner as to be electrically connected to said first semiconductor region.

2. The method as defined in claim 1, wherein said step of forming said Schottky contact regions and said element-segmenting regions within said respective unit regions, includes forming each of said element-segmenting regions into a frame shape and singly within a corresponding one of said unit regions.

3. The method as defined in claim 1, wherein said step of forming said Schottky contact regions and said element-segmenting regions within said respective unit regions, includes forming said element-segmenting regions in a latticed pattern.

4. The method as defined in claim 3, wherein said semiconductor substrate has one side length of 1.5 mm or more, and said second semiconductor region surrounded by said guard ring has an area which is 85% or more of a chip area of said semiconductor substrate.

5. The method as defined in claim 2, wherein said semiconductor substrate has one side length of 1.5 mm or more, and said second semiconductor region surrounded by said guard ring has an area which is 85% or more of a chip area of said semiconductor substrate.

6. The method as defined in claim 1, wherein said semiconductor substrate has one side length of 1.5 mm or more, and said second semiconductor region surrounded by said guard ring has an area which is 85% or more of a chip area of said semiconductor substrate.
